(19) United States
(12) Patent Application Publication
(10) Pub. No.: US 2026/0254462 A1
(43) Pub. Date: Aug. 27, 2026

(54) Universal Multi-Sensor Data Compression

(71) Applicant: Aarhus Universitet, Aarhus C (DK)

(72) Inventors: Gajraj Kuldeep, Aarhus C (DK); Qi Zhang, Aarhus C (DK)

(21) Appl. No.: 18/877,003

(22) PCT Filed: Jul. 5, 2023
(86) PCT No.: PCT/EP2023/068550

§ 371 Date: Dec. 19, 2024

(30) Foreign Application Priority Data
Jul. 6, 2022 (EP) 22183338.7

(51) Int. Cl. H03M 7/30; G06F 17/16

(52) U.S. Cl. CPC H03M 7/30; G06F 17/16

(57) ABSTRACT

The present disclosure regards a method for compression of a signal, of length, comprising data, the method comprising the steps of at least for a first level of decomposition, transforming the signal based on a first sparse matrix, of size × formed by an invertible matrix, representing a divisor-based signal decomposition for a first divisor to obtain a first vector of transformation coefficients, wherein =, and wherein the first vector comprises an initial component and detail components, . . . ,. The method further comprises the step of at least for a second level of decomposition, transforming the initial component based on a second sparse matrix, of size ×, where =, formed by an invertible matrix, representing a divisor-based signal decomposition for a second divisor, to obtain a second vector of transformation coefficients wherein =, and wherein the second vector comprises an initial component and detail components, . . . ,. After the transformation coefficients of the second vector of transformation coefficients, . . . , and detail components of the first vector, . . . , are quantized to obtain a quantized transformation vector and the signal is compressed based on the quantized transformation vector.

The present disclosure relates to signal compression devices, systems and methods for compression of signals.

### BACKGROUND

Internet of Things (IoT) have demonstrated an unprecedented potential to digitalize and automate diverse industrial processes and to provide intelligent services. On the one hand, with fast deployment of huge amount of IoT devices, the ever-increasing sensor data volume has posed many challenges in data acquisition, communication and storage. On the other hand, with the advancement of Microelectromechanical systems (MEMS) technology, multiple miniaturized sensors can be integrated into an IoT device. Integrating more sensors in a single device brings new opportunities for novel applications, while it poses challenges on the computation, memory and energy resource of IoT device. To enable sustainable growth of IoT ecosystem, efficient sensor data acquisition, transmission and storage solution is the key.

Uncompressed signals can consume considerable storage and transmission resources. Some of the main advantages of data compression are reduction in data storage, data transmission time and energy, and communication bandwidth. Because compressed signals require significantly less storage capacity and transmission resource than uncompressed signals, significant cost savings can be achieved. Data compression methods can be categorized into lossless compression or lossy compression. Lossy data compression methods provide better compression gain than the lossless compression methods at the cost of reconstructed signal quality. In general, the reconstructed signal quality depends on the level of compression, i.e. high compression ratio often leads to low signal quality. Oftentimes the user cannot get back original data after compression.

IoT devices generate a massive amount of data that needs to be transmitted to and processed at the data aggregator or edge/cloud. However, most of the connected IoT devices have constraints in memory, computation power, energy and bandwidth. Therefore, the state-of-the-art IoT systems call for lightweight computation and an efficient signal compression method.

### SUMMARY

Considering the prior art described above, it is a purpose of the present disclosure to overcome above-mentioned challenges.

The present approach relates in a first aspect to a method for compression of a signal x, of length N₁, comprising data. The method comprises the step of at least for a first level of decomposition, transforming the signal based on a first sparse matrix A₁, of size N₁×N₁ formed by an invertible matrix Φ_{d}_{₁}, representing a divisor-based signal decomposition for a first divisor d₁ to obtain a first vector s₁ of transformation coefficients, wherein s₁=A₁x, and wherein the first vector s₁ comprises an initial component v¹ and detail components

$${w}_{1}^{1} , {w}_{2}^{1} , … , {w}_{{d}_{1} - 1}^{1} .$$

The method further comprises the step of at least for a second level of decomposition, transforming the initial component based on a second sparse matrix A₂, of size N₂×N₂, where

$${N}_{2} = \frac{{N}_{1}}{{d}_{1}} ,$$

formed by an invertible matrix Φ_{d}_{₂}, representing a divisor-based signal decomposition for a second divisor d₂, to obtain a second vector s₂ of transformation coefficients wherein s₂=A₂v¹, and wherein the second vector s₂ comprises an initial component v² and detail components

$${w}_{1}^{2} , {w}_{2}^{2} , … , {w}_{{d}_{2} - 1}^{2} .$$

The method further comprises the step of quantizing the transformation coefficients of the second vector of transformation coefficients

$${v}^{2} , {w}_{1}^{2} , {w}_{2}^{2} , … , {w}_{{d}_{2} - 1}^{2}$$

and detail components of the first vector

$${w}_{1}^{1} , {w}_{2}^{1} , … , {w}_{{d}_{1} - 1}^{1} ,$$

to obtain a quantized transformation vector. Then the signal is compressed based on the quantized transformation vector.

The invertible matrices, Φ_{d}_{₁} and Φ_{d}_{₂}, may for example be provided by discrete cosine bases. Advantageously, the present disclosure leverages divisor-based signal decomposition, preferably with a discrete cosine transform. First, a divisor is selected based on the signal length, and the chosen divisor is used to construct a transformation matrix. Then, the transformation matrix can be applied to the signal to reduce time and frequency redundancy. Finally, on the transformed signal, an entropy coding can be applied to reduce coding redundancy.

The present approach solves the above-mentioned drawbacks of signal compression and provides first of all a signal compression method that is efficient in terms of memory, computation power, and energy. Due to reduction in resource usage, such as energy consumption, the present approach can offer a cost effective solution for signal compression while maintaining a high quality of the signal after decompression. The present approach offers an improved compression approach, by reducing the calculations needed for data compression. Generally, quantization and inverse quantization are very costly in terms of calculations required. A great advantage of the presently disclosed approach is that the memory, computation power and energy consumption can be reduced significantly. Because, with the above-mentioned sparse matrix composition, calculations, i.e., the number of multiplications, can be reduced. Consequently, it is possible to reduce the energy required for signal compression. The number of multiplications are reduced because of the divisor based multi-resolution decomposition, i.e., two level decomposition. For example, in general wavelet transforms are applied on radix-2 scale, whereas with the presently disclosed approach the above-mentioned sparse matrix can be applied on radix-d scale, where d is a divisor.

The state-of-the-art lossy compression methods are often designed and tailored for a particular signal type. For instance, JPEG is designed for images. For most Internet of Things (IoT) applications, an IoT device generates multi-modality sensor data, instead of a single type of signal. For instance, in e-Health applications, a smart watch collects photoplethysmogram (PPG), accelerometer, temperature and others. Due to lack of a unified data compression encoder in the conventional setting, it leads to poor utilization of constrained resources (e.g. energy, memory) at IoT devices. An important aspect of the presently disclosed approach can be that it better exploits both time and frequency redundancy in the signals due to the multi-level decomposition. The multi-level decomposition can be more generalized than the other existing decompositions, e.g., wavelet decomposition, and can better segregate frequency bands for both stationary and non-stationary signals. Therefore, the proposed approach can be applied to various types of signals, namely universality. This implies that the present approach can receive signals from one or more sensors. A wide range of data types can be received from a wide range of sensors in real-time and compressed.

The present disclosure relates in a second aspect to a computer program for compressing a signal comprising data and having instructions, which, when executed by a processing unit, cause the processing unit to carry out the steps of the presently disclosed method.

The present approach relates in a third aspect to a device, such as a wearable device, autonomous vehicle, smart meter, industrial monitoring device, or the like, having one or multiple sensors, wherein the device comprises a processing unit configured to execute the steps of the presently disclosed method. Advantageously, the proposed approach can be used for a variety of applications, such as e-Heath, Industry 4.0, industrial monitoring, process automation, structure health monitoring, predictive maintenance, smart agriculture, autonomous driving, and many others in real time. The device can be any device that can be connected wirelessly to a network and has the ability to transmit and communicate sensor data. The present novel data compression solution can achieve a superior compression performance for a wide range of sensor data types.

The signals of a variety of sensors can be received without the need for identifying the type of the sensor. The number of signals can be compressed separately by means of the above described multi-level decomposition to obtain a number of transformation vectors. After, entropy coding can be applied to a combination of the number of transformation vectors.

Many of the state-of-the-art lossy compression methods mostly require large signal samples to achieve a decent compression. However, in many applications data compression needs to be performed on a small number of signal samples due to device resource constraints or latency requirements in applications. Because of the above discussed properties, the proposed method works for small (e.g. 256) as well as large (e.g. greater than 256) signal lengths.

The presently disclosed compression approach can therefore achieve superior compression performance for a wide range of sensor data types while not compromising from the quality of the compressed data. The present approach can achieve reconstructed signal quality close to that of near lossless compression. The superior data compression can be provided for various types of signals, for example, images, audio, electrocardiogram (ECG), accelerometer, magnetometer, etc.

As a result, the present approach enables an efficient data compression, which can significantly reduce the transmission cost, via a reduction in transmission energy, communication bandwidth, thereby extending device battery lifetime, reducing the interference in a dense network, as well as reducing edge/cloud storage cost.

The present approach relates in a fourth aspect to a system comprising memory and compression and/or a processing unit, such as the device as described above.

### DESCRIPTION OF THE DRAWINGS

The present disclosure will in the following be described in greater detail with reference to the accompanying drawings:

FIG. 1: 1a illustrates an example electrocardiogram (ECG) signal of length 256 samples, 1b shows an exemplary illustration of a transformed signal of 1a, after applying the presently disclosed approach first time (one level decomposition) with divisor 8, 1c shows an exemplary illustration of a transformed signal after applying Wavelet transform three times (three level decomposition) on the ECG signal with symlet filter of length 8.

FIG. 2: 2a shows an example image, 2b shows an exemplary illustration of level one decomposition of image using divisor 8, 2c shows an exemplary illustration of level two decomposition of image using divisor 2.

FIG. 3 shows an example block diagram of one-dimensional compression method according to the present disclosure.

FIG. 4 shows an example block diagram of two-dimensional compression method according to the present disclosure.

FIG. 5 shows a plot illustrating an application of the presently disclosed compression approach on a real data signal. The graph shows two curves, wherein one curve shows the real measured data from an electrocardiogram measuring device and the other curve shows the result of the same electrocardiogram data after being compressed (and decompressed) by an example of the herein disclosed compression approach.

### DETAILED DESCRIPTION

### Level-One Signal Decomposition

The divisors of the present approach are preferably selected based on the signal length, and the chosen divisor is used to construct a transformation matrix. In an embodiment, the signal lengths N₁ and N₂ are divisible by the divisors d₁ and d₂, respectively. In a further embodiment, the first divisor and the second divisor are positive integers.

A sparse matrix A, can be constructed by means of an invertible matrix Φ_{d}.

In an embodiment, A₁ is formed by the invertible divisor matrix Φ_{d}_{₁} of size d₁×d₁ and wherein the matrix Φ_{d}_{₁} comprises one low-pass filter, e.g. in the form of the initial component, and high-pass filters, e.g. in the form of the detail components.

In an embodiment, A₂ is formed by the invertible divisor matrix Φ_{d}_{₂} of size d₂×d₂ and wherein the matrix Φ_{d}_{₂} comprises one low-pass filter, e.g. in the form of the initial component and high-pass filters, e.g. in the form of the detail components.

Thus, in general, A is a matrix of size N×N and formed by an arbitrary but fixed invertiblematrix Φ_{d} of size d×d. For a given d, the invertible matrix Φ_{d} can be represented as,

$${Φ}_{d} = [ \begin{matrix}{ϕ}_{1} \\ {ϕ}_{2} \\ ⋮ \\ {ϕ}_{dϕ}\end{matrix} ]$$

where vector Φᵢ is the i-th row of the matrix Φ_{d}.

The matrix A can be constructed in the following manner. First, by extending the row vectors of Φ_{d} up to length N by appending N−d zeros after that, shifted by kd, where k=0; 1; 2 . . . ; N/d−1. Thus, in an embodiment, the row vectors of Φ_{d}_{₁} is extended up to a signal length N₁ by appending N₁−d₁ zeros. This means that each of the row vectors can be extended up to the signal length N₁ by appending N₁−d₁ zeros. In a further embodiment, the row vectors of Φ_{d}_{₁} are shifted by kd₁ for each row, wherein k=0, 1, 2, . . . , N₁/d₁−1.

For example, the matrix constructed using the first row vector φ₁ can be given as,

$${[ \begin{matrix}{ϕ}_{1} & {0}_{1 \times d} & {0}_{1 \times d} & … & … & {0}_{1 \times d} \\ {0}_{1 \times d} & {ϕ}_{1} & {0}_{1 \times d} & … & … & {0}_{1 \times d} \\ \cdot & \cdot & \cdot & \cdot & \cdot & \cdot \\ {0}_{1 \times d} & {0}_{1 \times d} & {0}_{1 \times d} & & & {ϕ}_{1}\end{matrix} ]}_{\frac{N}{d} \times N}$$

This shifting operation results in N/d orthogonal vectors for each row vector φᵢ. Therefore, the total number of row vectors of the matrix A is N for the given matrix Φ_{d}. Matrix A can be represented as,

$$A = [ \begin{matrix}{ϕ}_{1} & {0}_{1 \times d} & {0}_{1 \times d} & … & {0}_{1 \times d} \\ {0}_{1 \times d} & {ϕ}_{1} & {0}_{1 \times d} & … & {0}_{1 \times d} \\ ⋮ & ⋮ & & & \\ {0}_{1 \times d} & {0}_{1 \times d} & {0}_{1 \times d} & … & {ϕ}_{1} \\ {ϕ}_{2} & {0}_{1 \times d} & {0}_{1 \times d} & … & {0}_{1 \times d} \\ {0}_{1 \times d} & {ϕ}_{2} & {0}_{1 \times d} & … & {0}_{1 \times d} \\ ⋮ & ⋮ & & & \\ {0}_{1 \times d} & {0}_{1 \times d} & {0}_{1 \times d} & … & {ϕ}_{2} \\ ⋮ & ⋮ & ⋮ & ⋮ & ⋮ \\ {ϕ}_{d} & {0}_{1 \times d} & {0}_{1 \times d} & … & {0}_{1 \times d} \\ {0}_{1 \times d} & {ϕ}_{d} & {0}_{1 \times d} & … & {0}_{1 \times d} \\ ⋮ & ⋮ & & & \\ {0}_{1 \times d} & {0}_{1 \times d} & {0}_{1 \times d} & … & {ϕ}_{d}\end{matrix} ]$$

This matrix can be invertible from construction. Hence, the signal x, of length N comprising data can be represented by s=Ax.

In an embodiment, Φ_{d}_{₁} and Φ_{d}_{₂} are provided by discrete cosine bases.

For example, if for any integer, d≥2, the entries such as dₖₘ, the k^{th} row and m^{th} column, of the matrix Φ_{d} are defined as,

$${d}_{km} = cos ( \frac{π k ( 2 m + 1 )}{2 d} ) ,$$

where 0≤k≤d−1 and 0≤m≤d−1.

A few examples of Φ_{d} are shown in the following.

For d=2, the matrix, Φ₂, is

$${Φ}_{2} = [ \begin{matrix}1 & 1 \\ 0.7071 & - 0.7071\end{matrix} ] .$$

For d=3, the matrix, Φ₃, is

$${Φ}_{3} = [ \begin{matrix}1 & 1 & 1 \\ 0.866 & 0 & - 0.866 \\ 0.5 & - 1 & 0.5\end{matrix} ] .$$

### Multi-Level Decomposition

The above example presents level one multiresolution decomposition. The proposed approach can however also be applied on multiple levels.

For a given signal x, of length N, let N₁=N, and there is Nᵢ₊₁=Nᵢ/dᵢ, Nᵢ has divisor dᵢ. For the divisor, d₁, the decomposed signal s₁=A₁x can be represented as,

$${s}_{1} = {v}^{1} ⊕ {w}_{1}^{1} ⊕ … ⊕ {w}_{{d}_{1} - 1}^{1}$$

where v¹ is an initial component,

$${w}_{i}^{1} s$$

are detail components for divisor d₁, and ⊕ is the direct sum. Now the component v¹ can be further decomposed into s₂=A₂v¹ using divisor d₂ and it can be represented as,

$${s}_{2} = {v}^{2} ⊕ {w}_{1}^{2} ⊕ … ⊕ {w}_{{d}_{1} - 1}^{2}$$

where v² is an initial component and

$${w}_{i}^{2} s$$

are detail components for divisor d₂.

Similarly for the k^{th} divisor dₖ the decomposition Sₖ=Aₖv^{k-1} is given as,

$${s}_{k} = {v}^{k} ⊕ {w}_{1}^{k} ⊕ … ⊕ {w}_{{d}_{k} - 1}^{k}$$

Using all k divisors, the decomposed signal y can be represented as,

$$y = {v}^{k} ⊕ {w}_{1}^{k} ⊕ … ⊕ {w}_{{d}_{k} - 1}^{k} ⊕ {w}_{1}^{k - 1} ⊕ … ⊕ {w}_{{d}_{k - 1} - 1}^{k - 1} ⊕ … ⊕ {w}_{1}^{1} ⊕ … ⊕ {w}_{{d}_{1} - 1}^{1} .$$

The initial component v¹ can be seen as a high-pass filter, whereas the detail components can be seen as low-pass filters.

As stated above the application of matrix A, on a one-dimensional signal typically results in one initial component and d₁-1 detail components. The probability distribution of the multi-level decomposition of any positive valued signal has bimodal distribution because of the one initial component and rest detail components. To make this distribution unimodal, mean value (average value) of the initial component can be calculated and subtracted from the initial component. For positive signals the quantization can be performed after subtracting a mean value from the initial component of the final decomposed transformation coefficients.

Furthermore, in an embodiment, the quantization is adaptive such that the transformation coefficients can be quantized using one or more thresholds. The quantization can be adaptive based on the signal characteristics. With the presently disclosed approach, the signal can be transformed in orthogonal subspaces that can be quantized using a different threshold, which could provide higher compression. For example, adaptive sub-band quantization can be used.

### Two-Dimensional Data Compression

Until here one-dimensional data compression approach has been described. The compression algorithm can also be applied for two-dimensional signal compression. In an embodiment, the signal is an image signal. Advantageously, the proposed approach can be a separable transform, which can be applied to image signals by first applying on rows then on columns. This implies that, in an embodiment, the method comprises the step of applying at least the first sparse matrix and at least the second sparse matrix on each dimension of a multi-dimensional signal, such as on each dimension of an image. In a further embodiment, the first sparse matrix and the second sparse matrix are applied first on rows and then on columns, respectively.

For example for a given image signal X, of size H×W, the data can be represented by

$$S = {A}_{1} {XB}_{1}^{T}$$

where the matrix A₁ is a first row sparse matrix, and B₁ is a column sparse matrix, which can be constructed using divisors for H and W, respectively. This process can be repeated on the first level initial component. According to the present disclosure, the width and height may be same or different for an image signal. For multi-dimensional signals a common divisor may be used for each dimension if the length of each dimension is equal, the divisor can also be different for each dimension and/or each level of decomposition.

For example, for an image, for the first level, the image height may have a divisor d_{1,1} and image width may have a divisor d_{1,2} and d_{1,1}≠d_{1,2}. Similarly, for the second level, the image height and image width of the initial component after the first level decomposition of an image can use different or same divisors d_{2,1} and d_{2,2}. In an embodiment therefore, the method comprises the step of applying at least the first sparse matrix and at least the second sparse matrix on at least one dimension of a multi-dimensional signal, and applying at least a third sparse matrix based on a third-divisor d_{1,2} and at least a fourth sparse matrix based on a fourth-divisor d_{2,2} on at least a second dimension of a multi-dimensional signal. In an embodiment, first the first-level decomposition is applied for all dimensions and afterwards the second-level decomposition is applied for all dimensions. This implies that for an image signal, first the first sparse matrix and the third sparse matrix based on divisors d_{1,1} and d_{1,2}, respectively are applied on the two dimensions of the image. After, for the second level decomposition, the second sparse matrix and the fourth sparse matrix based on divisors d_{2,1} and d_{2,2}, respectively are applied.

In an embodiment, the method comprises the step of, for the first level decomposition, applying the first sparse matrix and the third sparse matrix based on divisors d_{1,1} and d_{1,2}, on at least a first dimension and a second dimension of the two dimensional signal, respectively. In a further embodiment, the method comprises the step of, for the second level decomposition, applying the second sparse matrix and the fourth sparse matrix based on divisors d_{2,1} and d_{2,2}, on at least a first dimension and a second dimension of the two dimensional signal, respectively.

For two-dimensional data, at any one level decomposition there are one initial component and

$${d}_{1}^{2} - 1$$

detail components if image width and image height have a common divisor d₁. In an embodiment therefore, the application of matrix A₁ on a two-dimensional signal results in one initial component and

$${d}_{1}^{2} - 1$$

detail components. Decomposed and quantized image can be vectorized in one of the following ways:
Column/row stacking of the whole decomposed and quantized image.
Zig-zag decomposition of the whole decomposed and quantized image.
Column/row stacking of the each decomposed and quantized subspace.
Zig-zag decomposition of the each decomposed and quantized subspace.

### Universality

In an embodiment, the signal is received from one or more sensors. In an embodiment, the data signal is any natural signal such that the signal can be collected by a sensor. In an embodiment therefore, the signal is a time-series signal. The present approach leverages the multi-level decomposition which is a more generalized decomposition and can better segregate frequency bands compactly. In an embodiment, the transform can provide multiresolution at any radix, i.e, the divisor of the signal length, in addition, the radix of the transform can be selected based on the signal characteristics. Therefore, a wide range of signals can be compressed with superior performance using the proposed approach.

In an embodiment, the method comprises the step of receiving data in real time. In an embodiment, the signal represents real-time sensor data collected by one or more sensors, such as an audio sensor, magnetometer, accelerometer, electrocardiogram sensor, image sensor, or photoplethysmography sensor. The signal can comprise a plurality of sensor data acquired from a plurality of sensors configured such that each of the sensor data is transformed and quantized simultaneously. In an embodiment, the signal is received from a plurality of sensors.

In an embodiment, the method comprises the step of concatenating the quantized transformation vectors of one or more sensors into a single vector. In a further embodiment, entropy coding is applied on the single vector. In a further embodiment, the method comprises the step of applying an entropy coding technique, for example, arithmetic coding or Huffman coding, on the single vector such the signal from a plurality of sensors are compressed.

Additionally, in an embodiment, the method comprises the step of decompression to obtain reconstructed signals by performing entropy decoding, de-quantization, and inverse transformation for a level-wise decomposition.

Additionally, the present disclosure relates an IoT device, such as a wearable device, autonomous vehicle, smart meter, industrial monitoring device, having multiple sensors, wherein the IoT device comprises a processing unit configured to execute the steps of any one of the present approach. A processor may include a single processor or a plurality of processors. A processor may include a central processing unit (CPU) that carries out the instructions of the computer program.

The device can comprise at least one sensor for measuring data. The device can have access to an available dataset. The device can further comprise communication interface. In an embodiment, the device can be configured to transmit the compressed data. The device can collect and compress data and the compressed data can be transmitted through the communication interface. In an embodiment, the device can be further configured to store the compressed data.

Finally, the present disclosure relates a signal compression system, comprising a memory device and a compression unit, such as an IoT device. In a further embodiment, the system can be configured to execute the method of the present approach. The memory can store instructions or a computer program for executing the presented approach.

### DETAILED DESCRIPTION OF THE DRAWINGS

The presently disclosed approach provides an effective compression. In order to exemplify advantages of the present approach, the present approach can for example be compared with the Wavelet transform. For filter length of d, both the present approach and Wavelet transform require (d−1)N additions and dN multiplications. For this case the length of initial component is N/d and the length of combined detail components is (d−1)N/d for the current approach. Similarly for the Wavelet transform the length of initial component is N/2 and the detail component is also N/2, because for the Wavelet transform d=2. When d>2, the present approach takes the same number of additions and multiplications as Wavelet transform but provide higher compact representation.

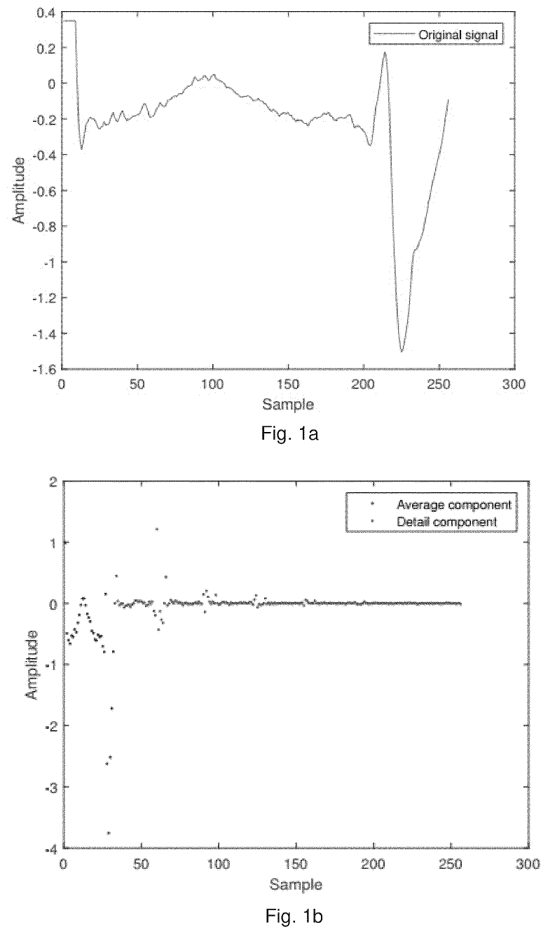

This effect can be observed from FIG. 1. FIG. 1a illustrates an example ECG signal of length 256. These are simulated for N=256 and filter length 8. FIG. 1b shows an exemplary illustration of a transformed signal of FIG. 1a, after applying the presently disclosed approach for the first time (one level decomposition) with divisor 8. FIG. 1c shows an exemplary illustration of a transformed signal after applying Wavelet transform three times (three level decomposition) on the ECG signal with symlet filter of length 8. It can be observed that to have the same effect as the present approach, the Wavelet transform has to be applied three times. That will result in 7*(256+128+64) additions and 8*(256+128+64) multiplications for Wavelet transform, whereas the present approach will only require 7*256 additions and 8*256 multiplications. Because the number of additions and multiplications are reduced; the computational cost related to data compression such as energy consumption can be reduced. Furthermore, a high quality data compression can be achieved within a shorter processing time.

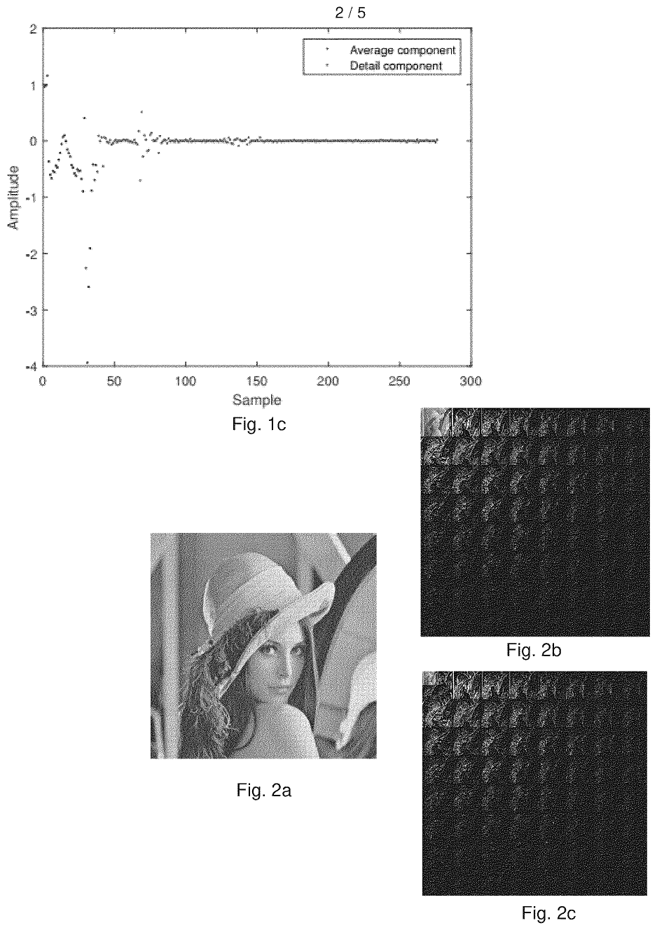

For image, at any one level decomposition there are one initial component and d²−1 detail components if image width and image height have common divisor d. An application of the present approach for two level decomposition of an image is shown in FIG. 2. Original image of size 512×512 is shown in FIG. 2a. Decomposition of the image is shown in FIG. 2b and FIG. 2c for divisors 8 and 2, respectively.

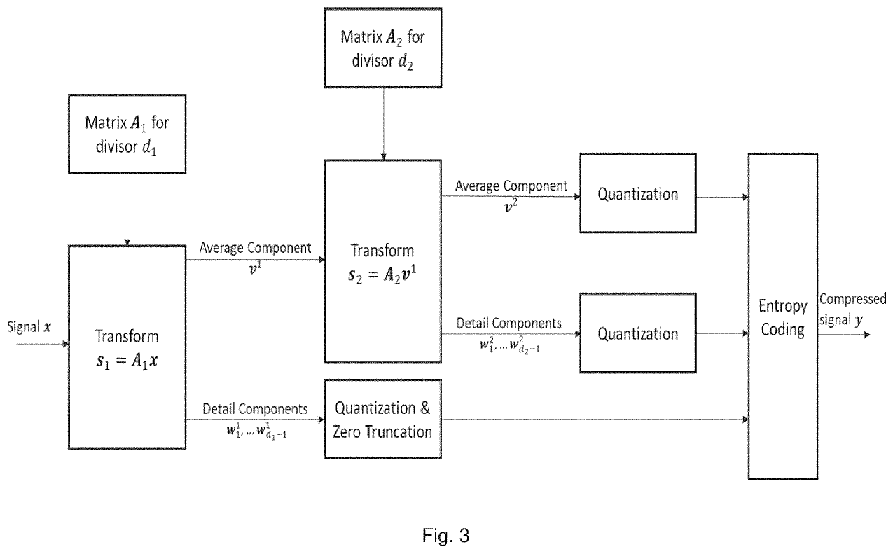

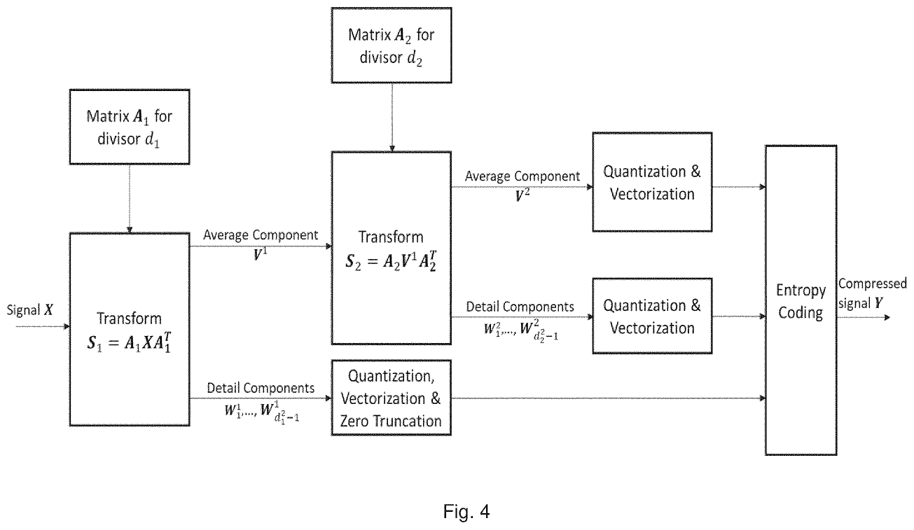

The compression algorithm for one-dimensional signal compression is shown in an exemplary block diagram in FIG. 3. The compression algorithm for two-dimensional signal compression is shown in an exemplary block diagram in FIG. 4.

FIG. 3 shows the compression steps for one-dimensional signals. First, signal is transformed using the first divisor then the initial component from the transformed signal is again transformed using the second divisor. Finally, all detail components and second level initial component are quantized and encoded using entropy coding. The encoded signal is represented as y.

FIG. 4 shows the compression steps for two-dimensional signals with same size in both dimensions. First, a two-dimensional signal is transformed using the first divisor by applying the transformation matrix on both dimensions, i.e., for an image this transformation is applied on rows and columns. The first step will generate one initial component and detail components. The initial component in this case is two-dimensional. Then, the initial component is transformed using the second divisor on both dimensions. After that, all the detail components from the first and second level are vectorized and quantized. Finally entropy coding is applied on the quantized vector.

For entropy coding, the presented example uses arithmetic coding. For one-dimensional algorithm, the quantization step, Q, with some positive value θ for the second level initial component is performed as,

$$Q ( {v}^{2} ) = ⌊ {v}^{2} \frac{1}{θ \sqrt{{d}_{1} {d}_{2}}} + 0.5 ⌋$$

where v² is the initial component.

The quantization step for the second level detail components is given as

$$Q ( {w}_{i}^{2} ) = ⌊ {w}_{i}^{2} \frac{\sqrt{2}}{θ \sqrt{{d}_{1} {d}_{2}}} + 0.5 ⌋ where {w}_{i}^{2}$$

is the i^{th} second level detail component.

For the first level detail components, the quantization step can be performed using,

$$Q ( {w}_{i}^{1} ) = ⌊ {w}_{i}^{1} \frac{\sqrt{2}}{θ \sqrt{{d}_{1}}} + 0.5 ⌋ where {w}_{i}^{1}$$

is the i^{th} first level detail component.

For two-dimensional algorithm shown in FIG. 4, the quantization step with some positive value θ for the second level initial component is performed as,

$$Q ( {V}^{2} ) = ⌊ {V}^{2} \frac{1}{θ {d}_{1} {d}_{2}} + 0.5 ⌋$$

where V² is the initial component.

The quantization step for the second level detail components is given as

$$Q ( {W}_{i}^{2} ) = ⌊ {W}_{i}^{2} \frac{2}{θ {d}_{1} {d}_{2}} + 0.5 ⌋ where {W}_{i}^{2}$$

is the i^{th} second level detail component.

For the first level detail components, the quantization step can be performed using,

$$Q ( {W}_{i}^{1} ) = ⌊ {W}_{i}^{1} \frac{2}{θ {d}_{1}} + 0.5 ⌋ where {W}_{i}^{1}$$

is the i^{th} first level detail component.

### Example

An example of a compression and decompression of raw electrocardiogram data according to the presently disclosed approach is provided in the following pages. The raw data comprises a vector of N₁=512 entries, wherein each entry is the electrocardiogram measured data at a given point in time. The presently disclosed compression method will be applied to the raw data and a decompression is performed afterwards to obtain a reconstructed signal in order to compare with the original signal. In this example, all measured numbers have been rounded to two decimal digits in order to reduce the length of the tables. On the other hand, the operations performed on the raw data and the compression method have been performed with the maximum accuracy provided by the raw data generator device, in this case an electrocardiogram device. The compression method may be applied to data comprising a number of decimal digits, such as two, five, ten or more.

The parameters for the transformation of the raw data are:

$${N}_{1} = 512 , {d}_{1} = 8 , {d}_{2} = 4 , θ = 10$$

The original raw signal of the electrocardiogram values measured by a device is x=[995; 995; 995; 995; 995; 995; 995; 995; 1000; 997; 995; 994; 992; 993; 992; 989; 988; 987; 990; 993; 989; 988; 986; 988; 993; 997; 993; 986; 983; 977; 979; 975; 974; 972; 969; 969; 969; 971; 973; 971; 969; 966; 966; 966; 966; 967; 965; 963; 967; 969; 969; 968; 967; 963; 966; 964; 968; 966; 964; 961; 960; 957; 952; 947; 947; 943; 933; 927; 927; 939; 958; 980; 1010; 1048; 1099; 1148; 1180; 1192; 1177; 1128; 1058; 991; 951; 937; 939; 950; 958; 959; 957; 955; 958; 959; 961; 962; 960; 957; 956; 959; 955; 957; 958; 957; 958; 959; 958; 958; 955; 953; 957; 959; 963; 960; 960; 958; 956; 957; 956; 955; 953; 953; 956; 958; 958; 958; 956; 954; 959; 959; 958; 958; 957; 957; 956; 958; 956; 954; 953; 954; 955; 958; 960; 957; 958; 955; 958; 957; 957; 955; 955; 953; 956; 956; 957; 958; 954; 954; 955; 957; 957; 957; 954; 953; 953; 955; 955; 957; 954; 952; 952; 952; 951; 952; 950; 947; 950; 952; 953; 952; 949; 949; 951; 951; 952; 952; 951; 950; 953; 958; 959; 959; 957; 956; 961; 964; 964; 966; 965; 966; 967; 969; 973; 974; 974; 971; 973; 975; 978; 975; 975; 973; 973; 976; 974; 973; 975; 973; 974; 974; 971; 972; 972; 971; 970; 971; 972; 969; 968; 966; 969; 970; 972; 968; 968; 967; 969; 969; 971; 970; 967; 966; 968; 969; 967; 968; 964; 964; 963; 965; 964; 962; 962; 963; 965; 967; 967; 966; 965; 962; 966; 965; 964; 963; 962; 959; 962; 964; 966; 962; 959; 958; 961; 964; 963; 962; 960; 958; 959; 961; 962; 963; 963; 962; 964; 963; 966; 964; 964; 963; 963; 966; 968; 965; 963; 961; 963; 965; 966; 968; 970; 969; 969; 970; 974; 974; 973; 979; 980; 983; 984; 983; 981; 978; 980; 979; 979; 979; 978; 977; 976; 977; 980; 982; 983; 975; 967; 967; 964; 962; 958; 958; 959; 961; 960; 961; 959; 956; 955; 956; 956; 954; 955; 953; 958; 957; 958; 960; 955; 953; 956; 958; 959; 958; 954; 951; 952; 948; 939; 935; 929; 922; 917; 923; 941; 964; 992; 1021; 1071; 1122; 1168; 1199; 1212; 1205; 1175; 1122; 1057; 1002; 970; 946; 934; 929; 933; 939; 946; 946; 947; 946; 948; 948; 948; 945; 947; 947; 947; 949; 945; 942; 942; 944; 945; 946; 943; 945; 947; 949; 946; 946; 943; 942; 942; 946; 946; 945; 943; 941; 944; 942; 943; 942; 941; 942; 944; 944; 945; 946; 943; 942; 946; 946; 947; 947; 942; 943; 945; 946; 949; 946; 945; 942; 944; 946; 946; 947; 943; 941; 941; 944; 945; 943; 941; 940; 940; 942; 941; 939; 940; 937; 938; 938; 940; 938; 934; 933; 934; 937; 935; 934; 933; 930; 932; 933; 934; 933; 930; 929; 932; 934; 935; 936; 937; 936; 942; 945; 950; 951; 952; 951; 956; 959; 961; 960; 958; 958; 960; 962; 964; 964; 960; 960; 961; 963; 963; 965; 960; 958; 963; 962; 964; 964; 960; 959; 962; 963]

The signal x is then transformed into the decomposed signal s₁=A₁x. The signal s₁ is generated after applying the matrix A₁ described in the previous sections, which is constructed using Φ_{d}_{₁} on the original signal. The matrix A₁ has been normalized using d₁.
[2814,28; 2811,46; 2796,25; 2787,06; 2746,4; 2732,26; 2734,03; 2713,52; 2670,74; 3175,62; 2737,56; 2711,4; 2707,87; 2709,28; 2703,98; 2707,51; 2706,1; 2704,68; 2703,62; 2704,33; 2698,67; 2689,13; 2690,19; 2702,21; 2730,14; 2755,24; 2754,89; 2748,88; 2741,45; 2738,98; 2732,26; 2728,02; 2724,48; 2720,95; 2718,12; 2725,54; 2727,31; 2743,57; 2772,21; 2766,56; 2750,65; 2712,46; 2702,56; 2707,16; 2662,26; 2811,1; 3231,48; 2666,85; 2678,52; 2672,86; 2673,22; 2668,97; 2668,27; 2671,45; 2673,92; 2669,33; 2658,72; 2648,82; 2638,92; 2640,69; 2689,13; 2717,76; 2718,83; 2721,3; 0; 8,22; 1,36; 21,05; 0,5; 3,08; 4,48; 18,16; −24,09; −140,45; 62,35; −3,38; −1,71; −4,56; 5,89; −0,58; 2,61; −3,39; 2,51; −0,52; −0,55; 2,14; −0,26; −7,13; −5,63; −3,12; 0,34; 3,13; −0,13; 0,51; 5,19; −4,64; 3,87; 2,78; −0,38; −1,12; 2,41; −6,42; −4,21; 3,37; 21,54; 0,11; −1,08; −0,71; 30,44; −187,01; 168,37; 9,99; 0,42; 2,43; 1,89; 2,42; −3,75; −0,38; 2,38; 2,02; 2,34; 4,49; 0,79; −7,48; −13,29; −4,44; −0,13; 1,78; 0; 1,58; −3,73; 0,69; 4,19; −0,38; −1,27; −3,35; 39,27; −100,4; 74,32; −3,73; 0,96; 5,03; 0; 1,42; −0,65; −4,62; 2,42; 3,08; −2,42; 1,69; 3,08; −5,58; −0,27; 2,42; −0,54; 0,84; 2,88; −3,73; 0,65; 0,92; −3,27; 2,5; 4,73; −1,77; 0; 1,31; −7,97; −0,19; −0,77; −3,81; 2,34; 4,38; −6,42; 44,46; −111,93; 28,58; −0,92; 5,11; −5,58; −1,27; 1,77; −4,96; −0,19; 4,19; −2,12; 1,19; 3,15; −1,77; −0,92; 4; −4,84; 1,12; 0; 2,55; −2,19; −2,95; 2,33; 2,89; −2,27; 3,65; −9,31; 18,02; 38; 3; −0,09; 2,73; 1,65; −3,67; 1,68; 1,1; −1,23; 1,65; 2,89; −2,71; 1,95; 1,82; −2,33; 0,6; 0,47; 0,86; 3,77; 1,88; −1,92; 2,66; 0,75; −5,88; 0,77; 1,03; −5,11; −2,74; −0,13; −0,3; −4,34; 1,63; −1,83; 2,21; 0,32; −23,78; 2,69; 13,54; −1,37; −0,46; −1,1; −3,2; 1,07; 0,77; −4,32; 1,54; 0,89; −4,52; 1,39; 0,53; −5,23; 1,66; 2,79; −3,56; 0; −0,71; 2,47; −3,18; −0,71; 0; −0,35; −1,06; 2,83; −17,68; 15,2; −0,35; 0,35; −2,47; 1,41; 0; −1,41; 0,71; 0,35; −1,06; −0,35; 2,12; 0,35; 1,77; 0; −3,18; 1,41; 1,06; −1,41; 0,35; 0,71; 0; 0; −0,71; −0,71; 0,35; −0,71; −1,41; −1,77; 1,06; −4,24; −0,71; −0,71; −2,47; −1,41; 13,79; −14,14; 4,6; 1,41; −2,12; −0,35; −1,77; 1,06; 0,71; 0,35; −2,83; 0,71; 0,71; −1,41; 0,35; 0,71; −0,35; −0,71; 1,06; 0; 1,63; 1,37; −1,02; 1,13; 1,08; 0,36; 0,07; −2,4; 8,11; 10,58; 1,23; −1,93; −0,16; 0,01; 0,88; 0,45; 0,38; 0,46; −1,2; 0,66; 0,24; −0,75; 1,04; −0,53; 0,48; 2,37; −1,13; 1,14; −0,37; −0,15; 0,58; 2,38; 0; −0,51; −0,27; −0,51; 0,72; −1,12; −0,03; 1,06; 1,27; 0,3; −2,03; 3,5; −3,81; −2,27; 4,52; 0,78; −1,59; 0,64; 0,34; −0,49; −0,51; −0,16; −0,24; 1,62; 0,66; −0,28; 1,45; 0,16; −0,09; 0,17; 2,15; 0; 0,11; 1,16; −2,96; −0,97; 0,92; −2,15; 0,24; 0,57; −5,87; 4,81; 1,16; −2,31; −1,7; 0; −2,12; 0,27; −1,91; −0,62; −0,89; 0,62; −1,47; −0,89; 0,4; −0,65; −0,62; −1,31; −0,73; −0,43; 1,16; −0,27; 0,38; 1,35; 0,49; 0,34; 0,35; 0; −0,54; −1,68; 0,46; 1,85; 0,05; −1,74; −1,43; 1,13; 1,1; −4,15; 1,56; −0,38; −0,59; 0,4; −2,15; −0,35; 2,82; 0,46; −0,97; −1,42; 1,04; 0,22; 0,35; −0,38; −0,51; 1,24; −0,08; 0; −0,47; −1,41; 1,94; −0,26; −0,11; 1,46; 0,58; −1,55; 1,35; 1,89; 0,71; −0,91; 1,49; −0,78; 0,67; −1,07; 1,07; 1,58; −1,03; −1,19; 0,13; 0,25; −0,55; −1,27; 1,48; −0,23; −0,82; 1,86; 0,76; −2,09; 0,1; 1,34; 0,83; 0,07; 2,03; 0,9; 0,89; −0,69; −0,2; −0,52; −0,85; 2,1; −0,05; −0,34; 1,59; −0,55; 2,22; 1,52; −0,6; −1,51; 0,54; 0,27; 0,07; 1,77; −0,68; 0,32; −0,07; 1,18; 0,46; 1,47; 0,14; −1,47; 0,12]

The elements of s₁ marked in bold before are the first initial component, v¹, of size

$$\frac{{N}_{1}}{{d}_{1}}$$

and the rest are the detail components. The signal s₁ is then transformed into the signal s₂=A₂v¹, wherein v¹ is the first initial component from the signal s₁ shown above. The signal s₂ is given below and is generated after applying the matrix A₂, which is constructed using Φ_{d}_{₁}, on the initial component v¹. The matrix A₂ has been normalized using d₂. The resulting signal s₂ is:
[5.604,53; 5.463,11; 5.647,66; 5.414,32; 5.409,37; 5.390,10; 5.494,57; 5.470,35; 5.444,55; 5.504,83; 5.436,41; 5.685,85; 5.346,79; 5.341,48; 5.293,58; 5.423,51; 21,90; 21,00; 91,97; 1,67; 1,44; −2,60; −12,15; 10,59; 0,07; −33,39; 31,09; −116,76; 6,14; −1,36; 14,46; −21,31; −3,18; −3,18; −265,52; 1,06; 1,06; 10,78; −15,56; −0,88; 5,48; −10,96; 21,39; −356,74; 0,71; −3,89; 5,83; −13,08; −2,57; 10,05; −297,17; −3,37; −0,21; −0,26; −5,30; −0,75; −2,13; 8,09; 5,30; 273,38; 2,81; 1,33; −1,59; −8,01]

Subsequently the step of quantizing the transformation coefficients of the second vector of transformation coefficients v² and detail components of the first vector is performed, to obtain a quantized transformation vector. The obtained quantized transformation vector is:
[560; 546; 565; 541; 541; 539; 549; 547; 544; 550; 544; 569; 535; 534; 529; 542; 2; 2; 9; 0; 0; 0; −1; 1; 0; −3; 3; −12; 1; 0; 1; −2; 0; 0; −27; 0; 0; 1; −2; 0; 1; −1; 2; −36; 0; 0; 1; −1; 0; 1; −30; 0; 0; 0; −1; 0; 0; 1; 1; 27; 0; 0; 0; −1; 0; 1; 0; 2; 0; 0; 0; 2; −2; −14; 6; 0; 0; 0; 1; 0; 0; 0; 0; 0; 0; 0; 0; −1; −1; 0; 0; 0; 0; 0; 1; 0; 0; 0; 0; 0; 0; −1; 0; 0; 2; 0; 0; 0; 3; −19; 17; 1; 0; 0; 0; 0; 0; 0; 0; 0; 0; 0; 0; −1; −1; 0; 0; 0; 0; 0; 0; 0; 0; 0; 0; 0; 4; −10; 7; 0; 0; 1; 0; 0; 0; 0; 0; 0; 0; 0; 0; −1; 0; 0; 0; 0; 0; 0; 0; 0; 0; 0; 0; 0; 0; 0; −1; 0; 0; 0; 0; 0; −1; 4; −11; 3; 0; 1; −1; 0; 0; 0; 0; 0; 0; 0; 0; 0; 0; 0; 0; 0; 0; 0; 0; 0; 0; 0; 0; 0; −1; 2; 4; 0; 0; 0; 0; 0; 0; 0; 0; 0; 0; 0; 0; 0; 0; 0; 0; 0; 0; 0; 0; 0; 0; −1; 0; 0; −1; 0; 0; 0; 0; 0; 0; 0; 0; −2; 0; 1; 0; 0; 0; 0; 0; 0; 0; 0; 0; 0; 0; 0; −1; 0; 0; 0; 0; 0; 0; 0; 0; 0; 0; 0; 0; −2; 2; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 1; −1; 0; 0; 0; 0; 0; 0; 0; 0; 0; 0; 0; 0; 0; 0; 0; 0; 0; 0; 0; 0; 0; 0; 0; 0; 0; 0; 1; 1; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; −1; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0]

Now, the quantized signal is de-quantized, as explained previously. The reconstructed transformed signal is:
[5600; 5460; 5650; 5410; 5410; 5390; 5490; 5470; 5440; 5500; 5440; 5690; 5350; 5340; 5290; 5420; 20; 20; 90; 0; 0; 0; −10; 10; 0; −30; 30; −120; 10; 0; 10; −20; 0; 0; −270; 0; 0; 10; −20; 0; 10; −10; 20; −360; 0; 0; 10; −10; 0; 10; −300; 0; 0; 0; −10; 0; 0; 10; 10; 270; 0; 0; 0; −10; 0; 10; 0; 20; 0; 0; 0; 20; −20; −140; 60; 0; 0; 0; 10; 0; 0; 0; 0; 0; 0; 0; 0; −10; −10; 0; 0; 0; 0; 0; 10; 0; 0; 0; 0; 0; 0; −10; 0; 0; 20; 0; 0; 0; 30; −190; 170; 10; 0; 0; 0; 0; 0; 0; 0; 0; 0; 0; 0; −10; −10; 0; 0; 0; 0; 0; 0; 0; 0; 0; 0; 0; 40; −100; 70; 0; 0; 10; 0; 0; 0; 0; 0; 0; 0; 0; 0; −1; 0; 0; 0; 0; 0; 0; 0; 0; 0; 0; 0; 0; 0; 0; −10; 0; 0; 0; 0; 0; −10; 40; −110; 30; 0; 10; −10; 0; 0; 0; 0; 0; 0; 0; 0; 0; 0; 0; 0; 0; 0; 0; 0; 0; 0; 0; 0; 0; −10; 20; 40; 0; 0; 0; 0; 0; 0; 0; 0; 0; 0; 0; 0; 0; 0; 0; 0; 0; 0; 0; 0; 0; 0; −10; 0; 0; −10; 0; 0; 0; 0; 0; 0; 0; 0; −20; 0; 10; 0; 0; 0; 0; 0; 0; 0; 0; 0; 0; 0; 0; −10; 0; 0; 0; 0; 0; 0; 0; 0; 0; 0; 0; 0; −20; 20; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 1; −10; 0; 0; 0; 0; 0; 0; 0; 0; 0; 0; 0; 0; 0; 0; 0; 0; 0; 0; 0; 0; 0; 0; 0; 0; 0; 0; 10; 10; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; −1; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0; 0]

Now, a first inverse transform using A₂ is applied on the de-quantization transform signal (shown in bold in the de-quantized signal above).

The reconstructed signal for the second divisor is given as:
[2813,07; 2805,41; 2794,59; 2786,93; 2745,77; 2728,88; 2731,12; 2714,23; 2667,62; 3180,34; 2739,66; 2712,38; 2705,00; 2705,00; 2705,00; 2705,00; 2705,00; 2705,00; 2705,00; 2705,00; 2700,00; 2690,00; 2690,00; 2700,00; 2725,76; 2758,83; 2751,17; 2744,24; 2741,53; 2737,71; 2732,29; 2728,47; 2725,00; 2715,00; 2715,00; 2725,00; 2728,11; 2740,35; 2769,65; 2761,89; 2752,30; 2711,59; 2708,41; 2707,70; 2659,67; 2816,14; 3233,86; 2670,33; 2681,53; 2677,71; 2672,29; 2668,47; 2670,00; 2670,00; 2670,00; 2670,00; 2656,53; 2642,71; 2637,29; 2643,47; 2689,23; 2716,12; 2713,88; 2720,77]

Now, the complete reconstructed signal after the second divisor is given as:
[2813,07; 2805,41; 2794,59; 2786,93; 2745,77; 2728,88; 2731,12; 2714,23; 2667,62; 3180,34; 2739,66; 2712,38; 2705,00; 2705,00; 2705,00; 2705,00; 2705,00; 2705,00; 2705,00; 2705,00; 2700,00; 2690,00; 2690,00; 2700,00; 2725,76; 2758,83; 2751,17; 2744,24; 2741,53; 2737,71; 2732,29; 2728,47; 2725,00; 2715,00; 2715,00; 2725,00; 2728,11; 2740,35; 2769,65; 2761,89; 2752,30; 2711,59; 2708,41; 2707,70; 2659,67; 2816,14; 3233,86; 2670,33; 2681,53; 2677,71; 2672,29; 2668,47; 2670,00; 2670,00; 2670,00; 2670,00; 2656,53; 2642,71; 2637,29; 2643,47; 2689,23; 2716,12; 2713,88; 2720,77; 0,00; 10,00; 0,00; 20,00; 0,00; 0,00; 0,00; 20,00; −20,00; −140,00; 60,00; 0,00; 0,00; 0,00; 10,00; 0,00; 0,00; 0,00; 0,00; 0,00; 0,00; 0,00; 0,00; −10,00; −10,00; 0,00; 0,00; 0,00; 0,00; 0,00; 10,00; 0,00; 0,00; 0,00; 0,00; 0,00; 0,00; −10,00; 0,00; 0,00; 20,00; 0,00; 0,00; 0,00; 30,00; −190,00; 170,00; 10,00; 0,00; 0,00; 0,00; 0,00; 0,00; 0,00; 0,00; 0,00; 0,00; 0,00; 0,00; −10,00; −10,00; 0,00; 0,00; 0,00; 0,00; 0,00; 0,00; 0,00; 0,00; 0,00; 0,00; 0,00; 40,00; −100,00; 70,00; 0,00; 0,00; 10,00; 0,00; 0,00; 0,00; 0,00; 0,00; 0,00; 0,00; 0,00; 0,00; −10,00; 0,00; 0,00; 0,00; 0,00; 0,00; 0,00; 0,00; 0,00; 0,00; 0,00; 0,00; 0,00; 0,00; 0,00; −10,00; 0,00; 0,00; 0,00; 0,00; 0,00; −10,00; 40,00; −110,00; 30,00; 0,00; 10,00; −10,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; −10,00; 20,00; 40,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; −10,00; 0,00; 0,00; −10,00; 0,00; 0,00; 0,00; 0,00; 0,00; 0,00; 0,00; 0,00; −20,00; 0,00; 10,00; 0,00; 0,00; 0,00; 0,00; 0,00; 0,00; 0,00; 0,00; 0,00; 0,00; 0,00; 0,00; −10,00; 0,00; 0,00; 0,00; 0,00; 0,00; 0,00; 0,00; 0,00; 0,00; 0,00; 0,00; 0,00; −20,00; 20,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 10,00; −10,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 10,00; 10,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; −10,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00; 0,00]

Finally, applying the inverse transform using A₁ on the above signal, the reconstructed signal of the original electrocardiogram raw data after performing the final inverse operations is given as:
[994,57; 994,57; 994,57; 994,57; 994,57; 994,57; 994,57; 994,57; 996,77; 996,02; 994,64; 992,84; 990,89; 989,09; 987,71; 986,96; 988,04; 988,04; 988,04; 988,04; 988,04; 988,04; 988,04; 988,04; 995,14; 993,64; 990,89; 987,28; 983,38; 979,77; 977,02; 975,52; 970,78; 970,78; 970,78; 970,78; 970,78; 970,78; 970,78; 970,78; 964,80; 964,80; 964,80; 964,80; 964,80; 964,80; 964,80; 964,80; 965,60; 965,60; 965,60; 965,60; 965,60; 965,60; 965,60; 965,60; 969,43; 967,94; 965,18; 961,58; 957,67; 954,07; 951,31; 949,82; 947,66; 943,46; 934,84; 925,49; 923,84; 936,14; 958,14; 975,59; 1011,68; 1051,92; 1098,28; 1150,40; 1180,51; 1193,73; 1182,03; 1126,80; 1056,85; 991,08; 946,18; 942,25; 944,45; 950,12; 958,80; 959,19; 958,97; 958,97; 958,97; 958,97; 958,97; 958,97; 958,97; 958,97; 956,36; 956,36; 956,36; 956,36; 956,36; 956,36; 956,36; 956,36; 960,98; 958,28; 954,45; 951,74; 951,74; 954,45; 958,28; 960,98; 961,27; 960,52; 959,14; 957,34; 955,39; 953,58; 952,20; 951,46; 956,36; 956,36; 956,36; 956,36; 956,36; 956,36; 956,36; 956,36; 956,36; 956,36; 956,36; 956,36; 956,36; 956,36; 956,36; 956,36; 956,36; 956,36; 956,36; 956,36; 956,36; 956,36; 956,36; 956,36; 956,36; 956,36; 956,36; 956,36; 956,36; 956,36; 956,36; 956,36; 956,36; 956,36; 956,36; 956,36; 956,36; 956,36; 956,36; 956,36; 954,59; 954,59; 954,59; 954,59; 954,59; 954,59; 954,59; 954,59; 951,06; 951,06; 951,06; 951,06; 951,06; 951,06; 951,06; 951,06; 951,06; 951,06; 951,06; 951,06; 951,06; 951,06; 951,06; 951,06; 945,07; 948,52; 953,73; 958,24; 960,19; 959,29; 956,84; 954,88; 958,80; 959,54; 960,92; 962,73; 964,68; 966,48; 967,86; 968,61; 975,39; 975,39; 975,39; 975,39; 975,39; 975,39; 975,39; 975,39; 972,69; 972,69; 972,69; 972,69; 972,69; 972,69; 972,69; 972,69; 970,23; 970,23; 970,23; 970,23; 970,23; 970,23; 970,23; 970,23; 969,28; 969,28; 969,28; 969,28; 969,28; 969,28; 969,28; 969,28; 967,93; 967,93; 967,93; 967,93; 967,93; 967,93; 967,93; 967,93; 970,92; 970,17; 968,79; 966,99; 965,04; 963,23; 961,85; 961,11; 964,66; 964,66; 964,66; 964,66; 964,66; 964,66; 964,66; 964,66; 963,43; 963,43; 963,43; 963,43; 963,43; 963,43; 963,43; 963,43; 955,74; 960,87; 964,80; 962,68; 957,12; 954,99; 958,92; 964,05; 959,90; 959,90; 959,90; 959,90; 959,90; 959,90; 959,90; 959,90; 963,43; 963,43; 963,43; 963,43; 963,43; 963,43; 963,43; 963,43; 960,37; 965,51; 969,44; 967,31; 961,75; 959,63; 963,56; 968,69; 963,96; 964,70; 966,08; 967,88; 969,84; 971,64; 973,02; 973,76; 974,60; 977,31; 981,13; 983,84; 983,84; 981,13; 977,31; 974,60; 976,48; 976,48; 976,48; 976,48; 976,48; 976,48; 976,48; 976,48; 982,89; 981,40; 978,64; 975,04; 971,14; 967,53; 964,77; 963,28; 958,69; 958,69; 958,69; 958,69; 958,69; 958,69; 958,69; 958,69; 957,57; 957,57; 957,57; 957,57; 957,57; 957,57; 957,57; 957,57; 957,31; 957,31; 957,31; 957,31; 957,31; 957,31; 957,31; 957,31; 950,43; 950,89; 950,58; 947,88; 942,03; 933,91; 925,95; 921,00; 916,18; 922,74; 941,50; 967,74; 993,69; 1027,44; 1076,81; 1119,16; 1172,36; 1196,50; 1215,15; 1207,20; 1174,04; 1120,70; 1055,15; 1005,63; 967,02; 953,03; 936,24; 928,44; 932,05; 940,49; 946,66; 948,90; 948,07; 948,07; 948,07; 948,07; 948,07; 948,07; 948,07; 948,07; 951,33; 948,63; 944,80; 942,09; 942,09; 944,80; 948,63; 951,33; 940,18; 942,89; 946,71; 949,42; 949,42; 946,71; 942,89; 940,18; 943,45; 943,45; 943,45; 943,45; 943,45; 943,45; 943,45; 943,45; 943,99; 943,99; 943,99; 943,99; 943,99; 943,99; 943,99; 943,99; 943,99; 943,99; 943,99; 943,99; 943,99; 943,99; 943,99; 943,99; 943,99; 943,99; 943,99; 943,99; 943,99; 943,99; 943,99; 943,99; 943,99; 943,99; 943,99; 943,99; 943,99; 943,99; 943,99; 943,99; 939,23; 939,23; 939,23; 939,23; 939,23; 939,23; 939,23; 939,23; 934,34; 934,34; 934,34; 934,34; 934,34; 934,34; 934,34; 934,34; 932,42; 932,42; 932,42; 932,42; 932,42; 932,42; 932,42; 932,42; 929,70; 930,45; 931,83; 933,63; 935,58; 937,38; 938,76; 939,51; 941,72; 947,60; 952,91; 952,59; 948,98; 948,66; 953,97; 959,85; 960,29; 960,29; 960,29; 960,29; 960,29; 960,29; 960,29; 960,29; 959,50; 959,50; 959,50; 959,50; 959,50; 959,50; 959,50; 959,50; 961,94; 961,94; 961,94; 961,94; 961,94; 961,94; 961,94; 961,94]

As seen above the components of the original raw data signal are similar to the components of the final reconstructed signal, within only a small percentage difference, demonstrating the low loss of the disclosed compression method. More specifically, the achieved compression ratio in this example is 6.7 using an arithmetic entropy coder.

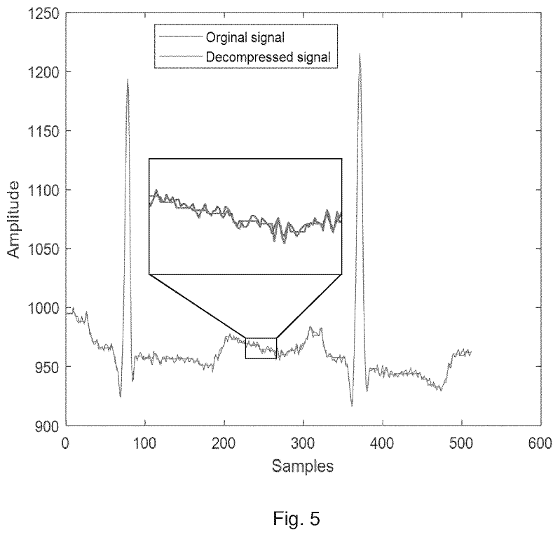

FIG. 5 shows a plot of two curves which is a comparison of the original ECG signal and the resulting signal after compression and decompression according to this example, i.e. a plot of the first and last matrices in the example. Both curves are superposed to a high degree along the whole data length, demonstrating the efficiency of the presently disclosed compression method and the high reliability of the processed signal in comparison with the original signal. A zoom in view of a part of both curves is shown in the center of the plot, in order to highlight the similarity of both raw data and processed data. A noisy-wavy component appears in the raw original data due to measurement uncertainties of the measuring device and the variability of the electrocardiogram itself. The compressed-decompressed signal greatly matches the original raw data, wherein the noisy-wavy component disappears and is transformed into plateaus.

### Items

1. A method for compression of a signal x, of length N₁, comprising data, the method comprising the steps of:
at least for a first level of decomposition, transforming the signal based on a first sparse matrix A₁, of size N₁×N₁ formed by an invertible matrix Φ_{d}_{₁}, representing a divisor-based signal decomposition for a first divisor d₁ to obtain a first decomposed vector s₁ of transformation coefficients, wherein s₁=A₁x, and wherein the first vector s₁ comprises an initial component v¹ and detail components

$${w}_{1}^{1} , {w}_{2}^{1} , … , {w}_{{d}_{1} - 1}^{1}$$

at least for a second level of decomposition, transforming the initial component based on a second sparse matrix A₂, of size N₂×N₂, where

$${N}_{2} = \frac{{N}_{1}}{{d}_{1}}$$

formed by an invertible matrix Φ_{d}_{₂}, representing a divisor-based signal decomposition for a second divisor d₂, to obtain a second decomposed vector s₂ of transformation coefficients wherein s₂=A₂v¹, and wherein the second vector s₂ comprises an initial component v² and detail components

$${w}_{1}^{2} , {w}_{2}^{2} , … , {w}_{{d}_{2} - 1}^{2}$$

quantizing the transformation coefficients of the second vector of transformation coefficients

$${v}^{2} , {w}_{1}^{2} , {w}_{2}^{2} , … , {w}_{{d}_{2} - 1}^{2}$$

and detail components of the first vector

$${w}_{1}^{1} , {w}_{2}^{1} , … , {w}_{{d}_{1} - 1}^{1} ,$$

to obtain a quantized transformation vector
compressing the signal based on the quantized transformation vector.

2. The method according to any of the preceding items, comprising the step of receiving signals from one or more sensors.

3. The method according to item 2, comprising the step of concatenating the quantized transformation vector of one or more sensors into a single vector.

4. The method according to item 3, comprising the step of applying entropy coding on the single vector.

5. The method according to any of the preceding items, wherein the signal of length of N₁ and N₂ are divisible by the divisors d₁ and d₂, respectively.

6. The method according to any of the preceding items, wherein the first divisor and the second divisor are positive integers.

7. The method according to any of the preceding items, wherein A₁ is formed by the invertible divisor matrix Φ_{d}_{₁} of size d₁×d₁ and wherein the matrix Φ_{d}_{₁}comprises one low-pass filter and high-pass filters.

8. The method according to any of the preceding items, wherein A₂ is formed by the invertible divisor matrix Φ_{d}_{₂} of size d₂×d₂ and wherein the matrix Φ_{d}_{₂} comprises one low-pass filter and high-pass filters.

9. The method according to any of the preceding items, wherein Φ_{d}_{₁} and Φ_{d}_{₂}, are provided by discrete cosine bases.

10. The method according to any of the preceding items, wherein each of the row vector of Φ_{d}_{₁} is extended up to a signal length N₁ by appending N₁−d₁ zeros.

11. The method according to any of the preceding items, wherein the row vectors of Φ_{d}_{₁} are shifted by kd₁ for each row, wherein k=0, 1, 2, . . . , N₁/d₁−1.

12. The method according to any of the preceding items, wherein the application of matrix A₁ on a one-dimensional signal results in one initial component and d₁-1 detail components.

13. The method according to any of the preceding items, wherein the application of matrix A₁ on a two-dimensional signal results in one initial component and

$${d}_{1}^{2} - 1$$

detail components.

14. The method according to any of the preceding items, further comprising the step of applying at least the first sparse matrix and at least the second sparse matrix on each dimension of a multi-dimensional signal, such as on each dimension of an image.

15. The method according to any of the preceding items, further comprising the step of applying at least the first sparse matrix and at least the second sparse matrix on at least one dimension of a multi-dimensional signal, and applying at least a third sparse matrix based on a third-divisor d_{1,2} and at least a fourth sparse matrix based on a fourth-divisor d_{2,2} on at least a second dimension of a multi-dimensional signal.

16. The method according to item 15, comprising the step of, for the first level decomposition, applying the first sparse matrix and the third sparse matrix based on divisors d_{1,1} and d_{1,2}, on at least a first dimension and a second dimension of the two dimensional signal, respectively.

17. The method according to any one of items 15-16, further comprising the step of, for the second level decomposition, applying the second sparse matrix and the fourth sparse matrix based on divisors d_{2,1} and d_{2,2}, on at least a second dimension of the two dimensional signal, respectively.

18. The method according to any of the preceding items, wherein the quantization is adaptive such that the transformation coefficients can be quantized using one or more thresholds.

19. The method according to any of the preceding items, wherein for positive signals the quantization is performed after subtracting a mean value from the initial component of the final decomposed transformation coefficients.

20. The method according to any one of the preceding items, further comprising the step of receiving data in real time.

21. The method according to any of the preceding items, wherein the data signal is any natural signal such that the signal can be collected by a sensor.

22. The method according to any of the preceding items, wherein the signal is a time-series signal.

23. The method according to any of the preceding items, wherein the signal is an image signal.

24. The method according to any of the preceding items, wherein the signal represents real-time sensor data collected by one or more sensors, such as an audio sensor, magnetometer, accelerometer, electrocardiogram sensor, image sensor, photoplethysmography sensor.

25. The method according to any of the preceding items, wherein the signal comprises a plurality of sensor data acquired from a plurality of sensors configured such that each of the sensor data is transformed and quantized simultaneously.

26. The method according to any of the preceding items, further comprising the step of decompressing to obtain reconstructed signals by performing entropy decoding, de-quantization, and inverse transformation for a level-wise decomposition.

27. A computer program for compressing a signal comprising data and having instructions, which, when executed by a processing unit, cause the processing unit to carry out the steps of the method according to any one of the items 1-26.

28. An IoT device, such as a wearable device, autonomous vehicle, smart meter, industrial monitoring device, having multiple sensors, wherein the IoT device comprises a processing unit configured to execute the steps of any one of the items 1-26.

29. The IoT device according to item 28, further configured to store the compressed data.

30. The IoT device according to any one of the items 28-29, further configured to transmit the compressed data.

31. A signal compression system, the system comprising
a memory device; and
a compression unit, such as an IoT device according to any one of items 28-30, wherein the system is configured to execute the steps of any one of items 1-26.

1-20. (canceled)

21. A method for compression of a signal x of length N₁ comprising data, the method comprising:
at least for a first level of decomposition, transforming the signal based on a first sparse matrix A₁, of size N₁×N₁ formed by an invertible matrix Φ_{d}_{₁} of size d₁×dᵢ, wherein dᵢ is a divisor of N₁, representing a divisor-based signal decomposition for a first divisor d₁ to obtain a first decomposed vector s₁ of transformation coefficients, wherein s₁=A₁x, and wherein the first decomposed vector s₁ comprises an initial component v¹ and detail components
$${w}_{1}^{1} , {w}_{2}^{1} , … , {w}_{{d}_{1} - 1}^{1} ,$$
and wherein each of one or more row vectors of Φ_{d}_{₁} is extended up to a signal length N₁ by appending N₁−d₁ zeros and wherein the one or more row vectors of Φ_{d}_{₁} are shifted by kd₁ for each row, wherein k=0, 1, 2, . . . , N₁/d₁−1;
at least for a second level of decomposition, transforming the initial component based on a second sparse matrix A₂, of size N₂×N₂, where
$${N}_{2} = \frac{{N}_{1}}{{d}_{1}} ,$$
formed by an invertible matrix Φ_{d}_{₂}, of size d₂×d₂, wherein d₂ is a divisor of N₂,, representing a divisor-based signal decomposition for a second divisor d₂, to obtain a second decomposed vector s₂ of transformation coefficients wherein s₂=A₂v¹, and wherein the second decomposed vector s₂ comprises an initial component v² and detail components
$${w}_{1}^{2} , {w}_{2}^{2} , … , {w}_{{d}_{2} - 1}^{2} ,$$
and wherein each of one or more row vectors of Φ_{d}_{₂} is extended up to a signal length N₂ by appending N₂−d₂ zeros and wherein the one or more row vectors of Φ_{d}_{₂} are shifted by kd₂ for each row, wherein k=0, 1, 2, . . . , N₂/d₂−1;
quantizing the transformation coefficients of the second decomposed vector of transformation coefficients
$${v}^{2} , {w}_{1}^{2} , {w}_{2}^{2} , … , {w}_{{d}_{2} - 1}^{2}$$
and detail components of the first decomposed vector
$${w}_{1}^{1} , {w}_{2}^{1} , … , {w}_{{d}_{2} - 1}^{1} ,$$
to obtain a quantized transformation vector; and
compressing the signal based on the quantized transformation vector.

22. The method according to claim 21, wherein the signal is received from one or more sensors, and wherein the quantized transformation vector of each signal from said one or more sensors is concatenated into a single vector, and wherein entropy coding is applied on the single vector such that the signal from the one or more sensors is compressed.

23. The method according to claim 21, wherein N₁ and N₂ are divisible by the first and second divisors d₁ and d₂, respectively, and wherein the first divisor and the second divisor are positive integers.

24. The method according to claim 21, wherein the initial component v¹ functions as a low-pass filter and wherein the detail components
$${w}_{1}^{1} , {w}_{2}^{1} , … , {w}_{{d}_{1} - 1}^{1}$$
function as high-pass filters.

25. The method according to claim 21, wherein the one or more row vectors of Φ_{d}_{₁} and the one or more row vectors of Φ_{d}_{₂} are provided by discrete cosine bases.

26. The method according to claim 21, wherein the application of matrix A₁ on a two-dimensional signal results in one initial component and
$${d}_{1}^{2} - 1$$
detail components.

27. The method according to claim 21, further comprising applying at least the first sparse matrix and at least the second sparse matrix on each dimension of a multi-dimensional signal.

28. The method according to claim 21, further comprising applying at least the first sparse matrix and at least the second sparse matrix on at least one dimension of a multi-dimensional signal, and applying at least a third sparse matrix based on a third-divisor d_{1,2} and at least a fourth sparse matrix based on a fourth-divisor d_{2,2} on at least a second dimension of the multi-dimensional signal.

29. The method according to claim 28, further comprising, for the first level decomposition, applying the first sparse matrix and the third sparse matrix based on divisors d_{1,1} and d_{1,2}, on at least a first dimension and a second dimension of a two dimensional signal, respectively, and for the second level decomposition, applying the second sparse matrix and the fourth sparse matrix based on divisors d_{2,1} and d_{2,2}, on at least a second dimension of the two dimensional signal, respectively.

30. The method according to claim 21, wherein the quantization is adaptive such that the transformation coefficients can be quantized using one or more thresholds and/or wherein for positive signals the quantization is performed after subtracting a mean value from the initial component.

31. The method according to claim 21, wherein the signal is received and compressed in real time.

32. The method according to claim 21, wherein the signal is a time-series signal or an image signal.

33. The method according to claim 21, wherein the signal is any natural signal such that the signal can be collected by a sensor.

34. The method according to claim 21, wherein the signal represents real-time sensor data collected by one or more sensors selected from the group of audio sensor, magnetometer, accelerometer, electrocardiogram sensor, image sensor, and photoplethysmography sensor.

35. The method according to claim 21, wherein the signal comprises a plurality of sensor data acquired from a plurality of sensors configured such that the sensor data from each of the plurality of sensors is transformed and quantized simultaneously.

36. An IoT (Internet of Things) device comprising:
a plurality of sensors; and
processing circuitry configured to:
at least for a first level of decomposition, transform the signal based on a first sparse matrix A₁, of size N₁×N₁ formed by an invertible matrix Φ_{d}_{₁} of size d₁×dᵢ, wherein d₁ is a divisor of N₁, representing a divisor-based signal decomposition for a first divisor d₁ to obtain a first decomposed vector s₁ of transformation coefficients, wherein s₁=A₁x, and wherein the first decomposed vector s₁ comprises an initial component v¹ and detail components
$${w}_{1}^{1} , {w}_{2}^{1} , … , {w}_{{d}_{1} - 1}^{1} ,$$
and wherein each of one or more row vectors of Φ_{d}_{₁} is extended up to a signal length N₁ by appending N₁−d₁ zeros and wherein the one or more row vectors of Φ_{d}_{₁} are shifted by kd₁ for each row, wherein k=0, 1, 2, . . . , N₁/d₁−1;
at least for a second level of decomposition, transform the initial component based on a second sparse matrix A₂, of size N₂×N₂, where
$${N}_{2} = \frac{{N}_{1}}{{d}_{1}} ,$$
formed by an invertible matrix Φ_{d}_{₂} of size d₂×d₂, wherein d₂ is a divisor of N₂,, representing a divisor-based signal decomposition for a second divisor d₂, to obtain a second decomposed vector s₂ of transformation coefficients wherein s₂=A₂v¹, and wherein the second decomposed vector s₂ comprises an initial component v² and detail components
$${w}_{1}^{2} , {w}_{2}^{2} , … , {w}_{{d}_{2} - 1}^{2} ,$$
and wherein each of one or more row vectors of Φ_{d}_{₂} is extended up to a signal length N₂ by appending N₂−d₂ zeros and wherein the one or more row vectors of Φ_{d}, are shifted by kd₂ for each row, wherein k=0, 1, 2, . . . , N₂/d₂−1;
quantize the transformation coefficients of the second decomposed vector of transformation coefficients
$${v}^{2} , {w}_{1}^{2} , {w}_{2}^{2} , … , {w}_{{d}_{2} - 1}^{2}$$
and detail components of the first decomposed vector
$${w}_{1}^{1} , {w}_{2}^{1} , … , {w}_{{d}_{1} - 1}^{1} ,$$
to obtain a quantized transformation vector; and
compress the signal based on the quantized transformation vector.

37. The IoT device according to claim 36, wherein the processing circuitry is further configured to store the compressed data.

38. The IoT device according to claim 36, wherein the processing circuitry is further configured to transmit the compressed data.

39. The IoT device according to claim 36, wherein the IoT device is a device selected from the group of: wearable device, autonomous vehicle, smart meter, and industrial monitoring device.

40. A signal compression system comprising:
a memory device; and
compression circuitry; and
wherein the signal compression system is configured to:
at least for a first level of decomposition, transform the signal based on a first sparse matrix A₁, of size N₁×N₁ formed by an invertible matrix Φ_{d}_{₁} of size d₁×d₁, wherein d₁ is a divisor of N₁, representing a divisor-based signal decomposition for a first divisor d₁ to obtain a first decomposed vector s₁ of transformation coefficients, wherein s₁=A₁x, and wherein the first decomposed vector s₁ comprises an initial component v¹ and detail components
$${w}_{1}^{1} , {w}_{2}^{1} , … , {w}_{{d}_{1} - 1}^{1} ,$$
and wherein each of one or more row vectors of Φ_{d}_{₁} is extended up to a signal length N₁ by appending N₁−d₁ zeros and wherein the one or more row vectors of Φ_{d}_{₁} are shifted by kd₁ for each row, wherein k=0, 1, 2, . . . , N₁/d₁−1;
at least for a second level of decomposition, transform the initial component based on a second sparse matrix A₂, of size N₂×N₂, where
$${N}_{2} = \frac{{N}_{1}}{{d}_{1}} ,$$
formed by an invertible matrix Φ_{d}_{₂} of size d₂×d₂, wherein d₂ is a divisor of N₂,, representing a divisor-based signal decomposition for a second divisor d₂, to obtain a second decomposed vector s₂ of transformation coefficients wherein s₂=A₂v¹, and wherein the second decomposed vector s₂ comprises an initial component v² and detail components
$${w}_{1}^{2} , {w}_{2}^{2} , … , {w}_{{d}_{2} - 1}^{2} ,$$
and wherein each of one or more row vectors of Φ_{d}_{₂} is extended up to a signal length N₂ by appending N₂−d₂ zeros and wherein the one or more row vectors of Φ_{d}_{₂} are shifted by kd₂ for each row, wherein k=0, 1, 2, . . . , N₂/d₂−1;
quantize the transformation coefficients of the second decomposed vector of transformation coefficients
$${v}^{2} , {w}_{1}^{2} , {w}_{2}^{2} , … , {w}_{{d}_{2} - 1}^{2}$$
and detail components of the first decomposed vector
$${w}_{1}^{1} , {w}_{2}^{1} , … , {w}_{{d}_{1} - 1}^{1} ,$$
to obtain a quantized transformation vector; and
compress the signal based on the quantized transformation vector.
